(19) United States
(12) Patent Application Publication
(10) Pub. No.: US 2008/0016682 A1
(43) Pub. Date: Jan. 24, 2008

(54) Method and apparatus for microstructure assembly

(75) Inventors: Ming-Hung Chou, Hsinchu City (TW); Wen-Jey Weng, Hsinchu County (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/519,092

(22) Filed: Sep. 12, 2006

(30) Foreign Application Priority Data
Jul. 18, 2006 (TW) 095126164

(51) Int. Cl. H05K 3/30

(52) U.S. Cl. 29/739; 29/832

(57) ABSTRACT

A method for microstructure assembly is disclosed, which comprises steps of: providing a carrier having a plurality of joint formed thereon; forming a pedestal on each joint; forming a droplet on each pedestal; placing a microstructure on each droplet; removing each droplet for enabling the corresponding microstructure to couple with the joint corresponding thereto. In the aforesaid method, the use of the plural droplets is to align the plural microstructures in an automatic manner so as to enable each microstructure to couple with its corresponding joint smoothly. In a preferred aspect, an apparatus for microstructure assembly can be provided with respect to the aforesaid method, which is capable of automating the process of microstructure alignment and assembly.

### FIELD OF THE INVENTION

The present invention relates to a component alignment method and the manufacturing apparatus using the same, and more particularly, to a method and apparatus for microstructure assembly capable of rapidly packaging microstructures in high volume by the use of droplets for aligning microstructures and an automated transportation and manufacturing process.

### BACKGROUND OF THE INVENTION

The miniaturization trend in microelectronics industry continues to drive the development of smaller, higher-efficiency devices, that the radio frequency identification (RFID) tag and the light emitting diode (LED) can be considered as the representative products of such trend since both are formed on a miniature-sized chips and are require in high volume. Conventionally, in the manufacturing cost of such products, the cost of assembly is accounted for more than 20% of the overall manufacturing cost. Therefore, it is worth the relating industry the effort to focus on developing an improved manufacturing method capable of reducing such assembly cost.

Conventional assembly methods can be categorized into three kinds: fluid self-assembly (FSA), pick-and-place, and assembling by thimbles. Please refer to FIG. 1, which is a schematic diagram showing a process of fluid self-assembly (FSA). In this fluid self-assembly (FSA) process, a great amount of microstructures 21, floating and flowing with the flow of a solution 1, are floated into place across a surface area of a silicon substrate 20 that has an array of holes 22 formed thereon by an etching process. As each microstructure 21 approaches a hole 22, it fits into the hole 22 perfectly because it fits only one way. In this manner, the plural microstructures can be aligned and orientated.

Although FSA process is successful in aligning and orientating microstructures, it still has shortcomings as following: (1) the backside of each microstructure must be specifically shaped to fit into its corresponding hole while the surface of each microstructure must be processed into hydrophobic surface. (2) the apparatus of FSA process is huge since it required many -facilities, such as recycling and recovering device, solution control device and drying device, etc. (3) since the microstructures are required to be soaked in the solution for a certain period of time, they might be damaged by the soaking. (4) there should be much more than actually required amount of microstructures floating in the solution so that the probability of fitting a microstructure in each hole can be increased.

As for the pick-and-place method, it is usually performed by using a robotic arm as a means for fetching, transporting and aligning microstructures such that the microstructures can be placed on a substrate at positions corresponding thereto. However, the pick-and-place method has shortcomings as following: (1) a complete set of devices, including position sensors, signal processors and position adjusting devices, etc., are required so that the apparatus of the pick-and-place method can be very complicated. (2) by the pick-and-place method, the aligning and orientating requires a comparatively longer time to achieve. (3) the smaller the microstructure is, the more costly the aligning by the pick-and-place method will be, since the precision tuning of the robotic arm is hard to achieve. (4) as the robotic arm can only align one microstructure at one operation, the yield per unit time is low. (5) it is not difficult to be used for aligning microstructure that is smaller than a centimeter.

Please refer to FIG. 2A and FIG. 2B, which are schematic diagrams showing an assembling by thimbles. In FIG. 2A, a plurality of microstructures 33 are disposed on a platform 32, in which a plurality of thimbles 34 are arranged at positions corresponding to the plural microstructures 33, while a conveyer belt 30 having a plurality of joints 31 is positioned over the plural microstructures 33. In FIG. 2B, as one of the plural joints 31 of the conveyer belt 30 is aligned to the target point 35 of one of the plural microstructures 33, the thimbles 34 will push the corresponding microstructures 33 to rise for jointing the risen microstructures 33 with corresponding joints 31.

However, the aforesaid method of assembling by thimbles still has shortcomings as following: (1) it is costly since it requires very high accuracy. (2) the conveyer belt is easy to deform, and as more than one thimble are used for rising more than one microstructures for performing multiple jointing at a same time, the accuracy of alignment is hard to achieve.

Therefore, considering the requirement of mass-production, manufacturing cost and precision alignment, a method and apparatus for microstructure assembly capable of rapidly aligning microstructures is in great need.

### SUMMARY OF THE INVENTION

It is the primary object of the present invention to provide a method and apparatus for microstructure assembly, capable of accurately aligning microstructures to their corresponding positions by a process of placing the microstructures on droplets formed on pedestals and then removing the droplets.

It is another object of the invention to provide a method and apparatus for microstructure assembly, capable of being implemented by an automated packaging process integrating automated transportation devices and all sorts of packaging devices, by which a great amount of microstructures can be rapidly aligned and thus the manufacturing cost can be reduced.

It is yet another object of the invention to provide a method and apparatus for microstructure assembly, capable of being implemented by an automated packaging process integrating automated transportation devices and all sorts of packaging devices, by which the microstructures are not restricted to be carried by a specified carrier of assembly, instead they can be carried by a variety of carriers while being assembling.

To achieve the above objects, the present invention provides a method for microstructure assembly, comprising steps of: providing a carrier having a plurality of joint formed thereon; forming a pedestal on each joint; forming a droplet on each pedestal; placing a microstructure on each droplet; removing each droplet for enabling the corresponding microstructure to couple with the joint corresponding thereto; and using a holding means for securing each microstructure upon the carrier.

Preferably, each pedestal can be made of a material selected from the group consisting a hydrophobic material and a hydrophilic material.

Preferably, the carrier can be a roll-to-roll carrier or a substrate.

Preferably, the removal of the droplets can be performed by a means selected from the group consisting of allowing to dry naturally, and drying by heating.

Preferably, the pedestal can be formed by a means selected from the group consisting of transfer printing by a roller, and screen printing.

Preferably, the droplet can be formed by a means selected from the group consisting of a nebulization means, a soaking means, a dripping means and a means of arranging a solution in a container with a plurality of orifices while using the plural orifices for forming droplets. In a preferred aspect, a pressure can be exerted upon the solution in the container.

Preferably, the droplet can be made of a material selected from the group consisting of water, oil, alcohol, liquid-state paste, and liquid-state metal.

Preferably, the securing of each microstructure upon the carrier further comprises steps of: coating a paste on each microstructure; and curing the paste.

To achieve the above objects, the present invention provides a method for microstructure assembly, comprising steps of: providing a carrier having a plurality of joint formed thereon; forming a layer of paste on each joint; forming a droplet on the layer of paste corresponding to each joint; providing and placing a microstructure on each droplet; removing each droplet for enabling each microstructure to couple with the joint corresponding thereto; and jointing each microstructure with the layer of paste of the joint corresponding thereto.

Preferably, the jointing of each microstructure with the layer of paste of the joint corresponding thereto can be performed by a means selected from the group consisting of a heating means, and an ultrasonic means.

To achieve the above objects, the present invention provides an apparatus for microstructure assembly, which comprises: a transportation device, for transporting a carrier having a plurality of joints formed thereon; a transfer imprinting device, for receiving the carrier while forming a pedestal on each joint; a droplet formation device, for receiving the carrier with pedestals formed thereon while forming a droplet on each pedestal; a chip placing device, for providing a plurality of microstructures while placing each microstructure on a droplet corresponding thereto; a droplet removal device, for receiving the carrier carrying the plural microstructures while removing each droplet for jointing each microstructure with its corresponding joint; and a pasting device, for receiving the carrier exiting from the droplet removal device while proving a paste to the carrier for securing each microstructure on the carrier.

Preferably, the transportation device can be a roll-to-roll transportation device or a platform transportation device.

Preferably, the droplet removal device can be a device selected from the group consisting of a wind blower and a baking device.

Preferably, the chip placing device can be a device selected from the group consisting of a roller device and a screen printing device.

Preferably, the droplet formation device further comprises: a container, having an accommodating space for receiving a liquid, and a plurality of orifices formed on a side thereof while each being channeling to the accommodating space;, and a pressure unit, for providing a pressure to be exerted on the liquid. In addition, the droplet formation device further comprises a nebulization unit, which can be a piezoelectric nebulizer, a thermal-bubble type nebulizer, or an ultrasonic nebulizer.

Preferably, the pasting device further comprises: a pasting unit, for providing a paste to be coated on each microstructure; a baking unit, for curing the paste; and a cooling unit, for cooling the paste.

To achieve the above objects, the present invention provides an apparatus for microstructure assembly, which comprises: a transportation device, for transporting a carrier having a plurality of joints formed thereon; a transfer imprinting device, for receiving the carrier while forming a layer of a paste on each joint; a droplet formation device, for receiving the carrier coated with the paste while forming a droplet on the layer of paste corresponding to each joint; a chip placing device, for providing a plurality of microstructures while placing each microstructure on a droplet corresponding thereto; a droplet removal device, for receiving the carrier carrying the plural microstructures while removing each droplet for jointing each microstructure with its corresponding joint; and a jointing device, capable of providing energy for jointing each microstructure with its corresponding layer of paste.

Preferably, the joint device can be an ultrasonic bonding device or a heating device.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is a schematic diagram showing a process of fluid self-assembly (FSA).

FIG. 2A and FIG. 2B are schematic diagrams showing an assembling by thimbles.

FIG. 3 is a flow chart depicting a method for microstructure assembly according to a first preferred embodiment of the invention.

FIG. 4 is a schematic diagram showing an assembly apparatus according to a first preferred embodiment of the invention.

FIG. 5A is a schematic view of a carrier according to a preferred embodiment of the invention.

FIG. 5B is a schematic diagram showing a plurality of joints formed on a carrier of the invention.

FIG. 6A and FIG. 6B are schematic diagrams showing two chip placing devices used in an assembly apparatus respectively according to a first and a second preferred embodiments of the invention.

FIG. 6C is a schematic diagram showing pedestals formed on a carrier according to the present invention.

FIG. 7 is a schematic diagram showing a droplet formation device according to a first embodiment of the invention.

FIG. 8A is a schematic diagram showing a droplet formation device according to a second embodiment of the invention.

FIG. 8B is a schematic diagram showing a droplet formation device according to a third embodiment of the invention.

FIG. 9A is a schematic diagram showing a chip placing device of the invention.

FIG. 9B is a schematic diagram showing the placing of microstructures on droplets.

FIG. 10A is a schematic diagram showing the microstructures being placed on pedestals corresponding thereto after the droplets are removed.

FIG. 10B is a schematic diagram showing the microstructures being secured by a paste.

FIG. 11A is a schematic view of a carrier according to another preferred embodiment of the invention.

FIG. 11B is a schematic diagram showing another assembly apparatus according to a second preferred embodiment of the invention.

FIG. 12 is a flow chart depicting a method for microstructure assembly according to a second preferred embodiment of the invention.

FIG. 13 is a schematic diagram showing yet another assembly apparatus according to a third preferred embodiment of the invention.

FIG. 14A is a schematic diagram showing the placing of microstructures on droplets.

FIG. 14B is a schematic diagram showing the jointing of the microstructures with layers of paste corresponding thereto.

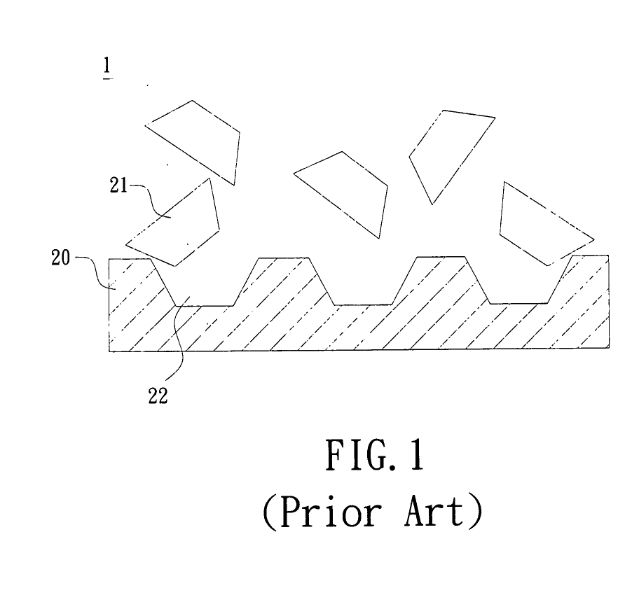

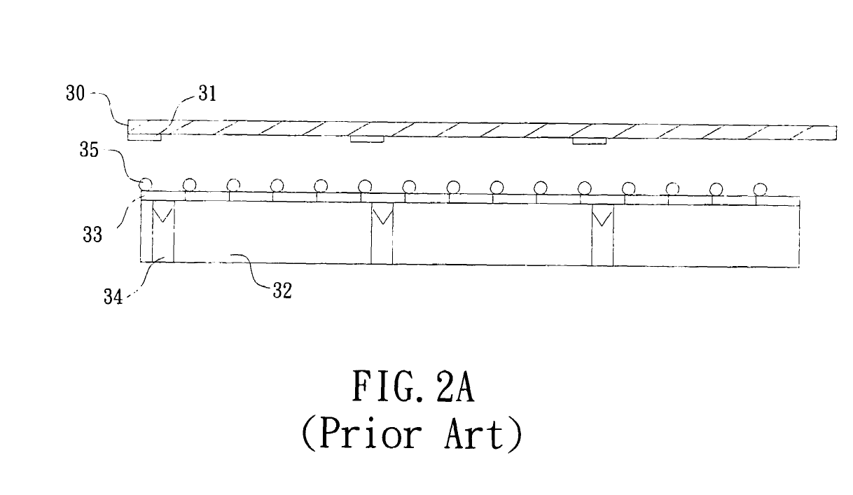

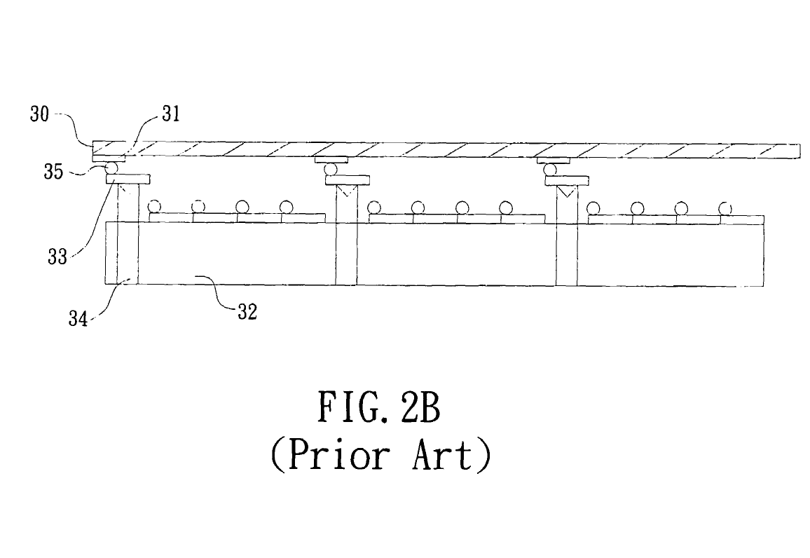

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

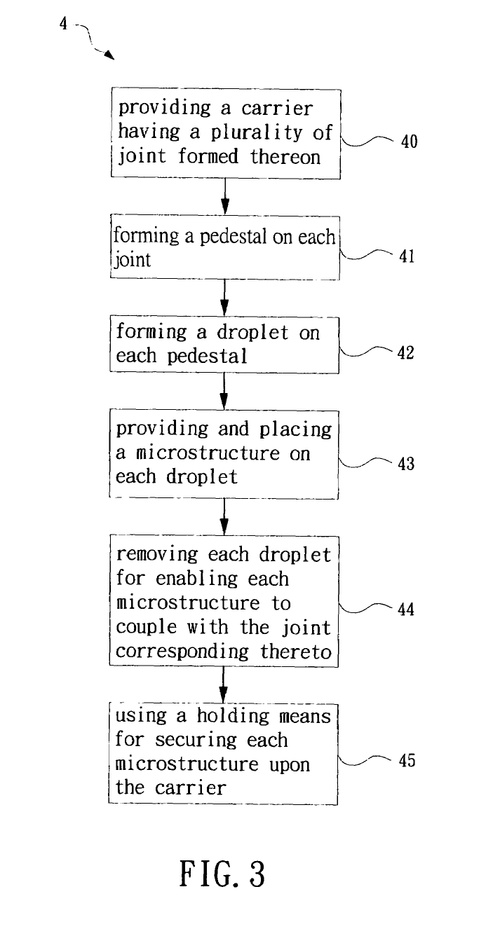

Please refer to FIG. 3, which is a flow chart depicting a method for microstructure assembly according to a first preferred embodiment of the invention. The flow 4 starts at step 40. At step 40, a carrier 40 is provided, which has a plurality of joint formed thereon to be used for forming electrical connections with microstructures, and then the flow proceeds to step 41. In a preferred aspect, the carrier 40 can be a roll-to-roll carrier, or a flexible substrate or printed circuit board, previously cut into a specific size, and each microstructure can be a RFID chip, a LED chip or other passive components. At step 41, a pedestal is formed on each joint, whereas the pedestal can be made of a hydrophobic material or a hydrophilic material, and then the flow proceeds to step 42. At step 42, a droplet is formed on each pedestal, whereas the droplet can be made of a material selected from the group consisting of water, oil, alcohol, liquid-state paste, and liquid-state metal, and then the flow proceeds to step 43. At step 43, a microstructure is provided and placed on each droplet, and then the flow proceeds to step 44. At step 44, each droplet is removed for enabling each microstructure to couple with the joint corresponding thereto, and then the flow proceeds to step 45. At step 45, a holding means is adopted for securing each microstructure upon the carrier.

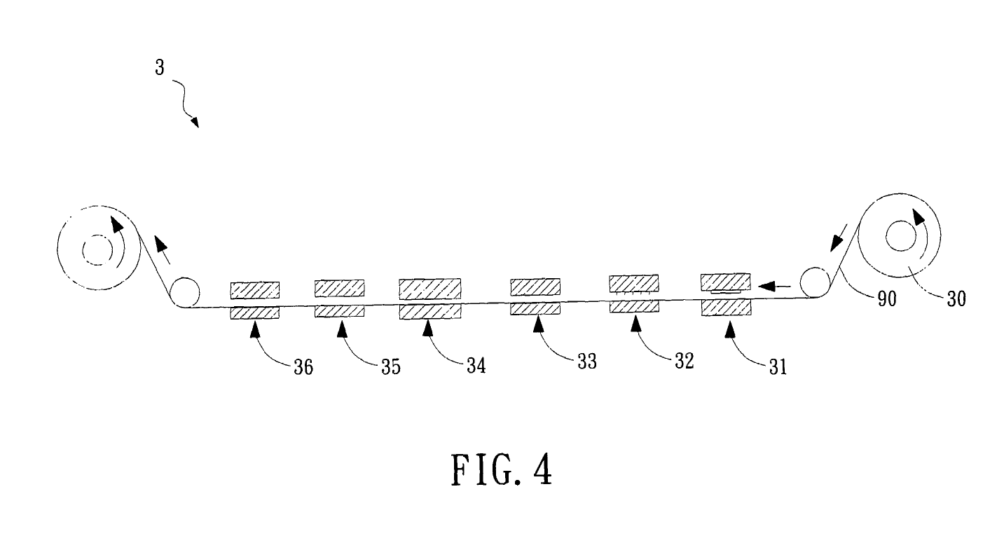

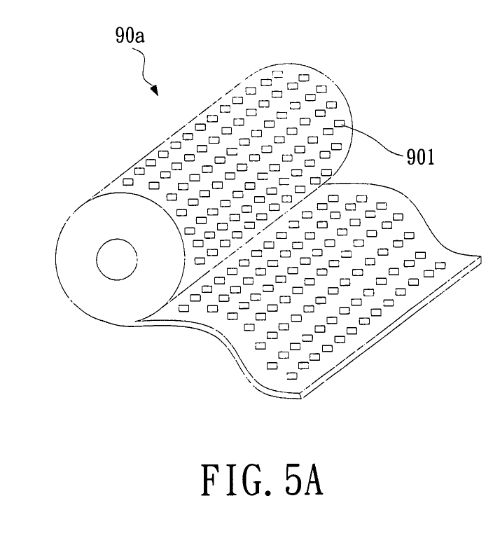

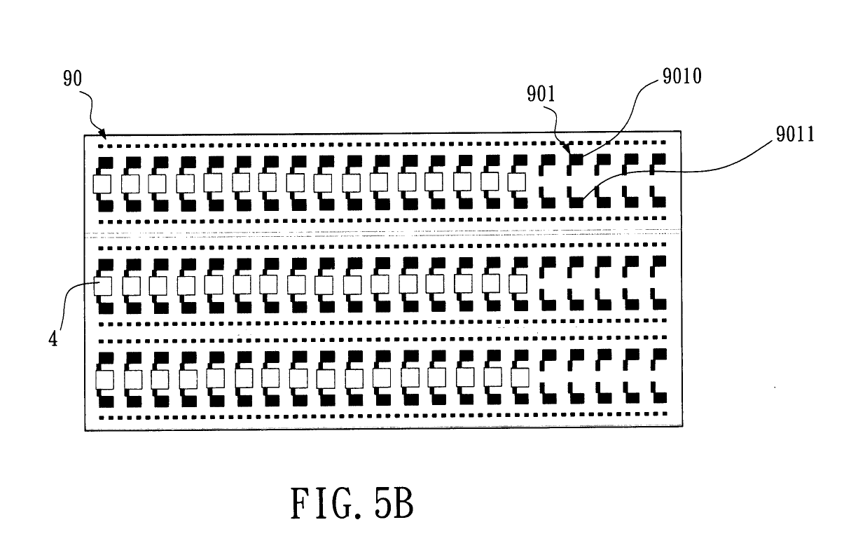

Please refer to FIG. 4, which is a schematic diagram showing an assembly apparatus according to a first preferred embodiment of the invention. The assembly apparatus 3 of FIG. 4 is provided for enabling the aforesaid method for microstructure assembly, which comprises: a transportation device 30, a transfer imprinting device 31, a droplet formation device 32, a chip placing device 33, a droplet removal device 34, and a pasting device 35. The transportation device 30 is used for transporting a carrier 90 having a plurality of joints formed thereon. Please refer to FIG. SA, which is a schematic view of a carrier according to a preferred embodiment of the invention. The carrier 90a of FIG. SA is a roll-to-roll carrier 90a having a plurality of joints 901 formed thereon. As seen in FIG. 5B, each joint 901 is comprised of two electrical terminals 9010, 9011. It is noted that the transportation device illustrated in this first embodiment is a roll-to-roll device.

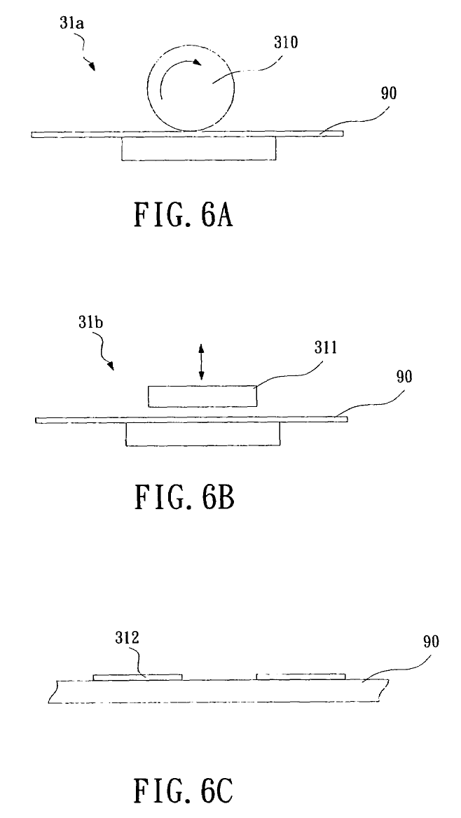

Moreover, in FIG. 4, the transfer imprinting device 31 is used or receiving the carrier 90 while forming a pedestal on each joint 901, whereas each pedestal can be made of a hydrophobic material or a hydrophilic material. Please refer to FIG. 6A and FIG. 6B, which are schematic diagrams showing two chip placing devices used in an assembly apparatus respectively according to a first and a second preferred embodiments of the invention. In FIG. 6A, the transfer imprinting device 31a is substantially a roller 310 capable of forming pedestals on the carrier 90 by a manner of transfer imprinting. In FIG. 6B, the transfer imprinting device 31b is substantially a screen plate 311 capable of printing pedestals on the carrier 90. It is noted that the pedestals 312, no matter it is formed by transfer imprinting or screen printing, are formed on the carrier 90, as those shown in FIG. 6C.

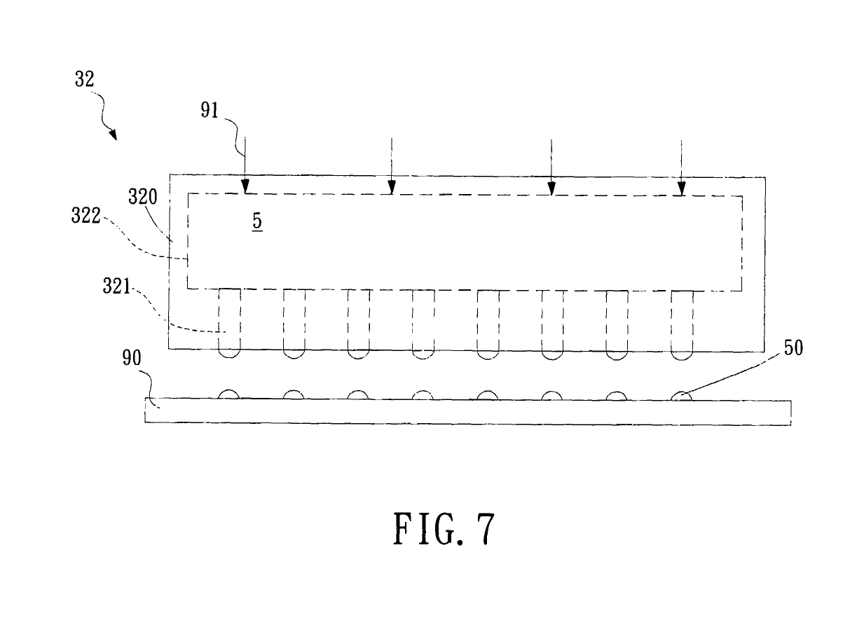

In addition, in FIG. 4, the droplet formation device 32 is capable of receiving the carrier. 90 with pedestals formed thereon while forming a droplet on each pedestal. Please refer to FIG.7, which is a schematic diagram showing a droplet formation device according to a first embodiment of the invention. In FIG. 7, the droplet formation device 32 further comprises: a container 320, having an accommodating space 322 for receiving a liquid 5, and a plurality of orifices 321 formed on a side thereof while each being channeling to the accommodating space 320.Preferably, the droplet formation device 32 further comprises: a pressure unit, for providing a pressure 91 to be exerted on the liquid 5 and thus enabling droplets 50 to be formed on the carrier through the plural orifices 321. In addition, the droplet formation device 32 can further comprises a nebulization unit, which can be nebulize the liquid so as to form droplets 50 on each pedestal since each pedestal either is made of hydrophobic material, or has a hydrophobic coating.

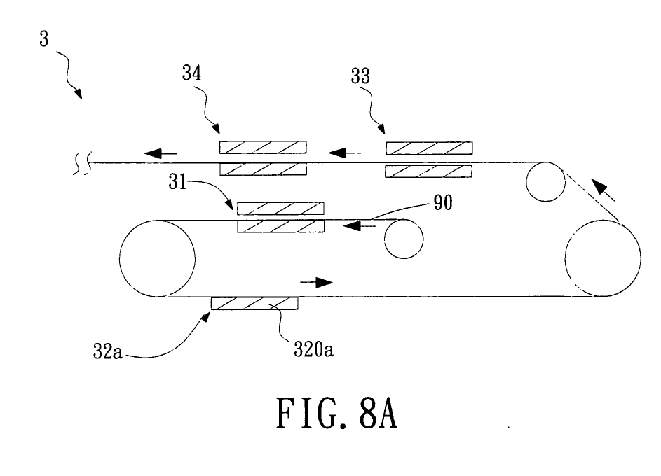

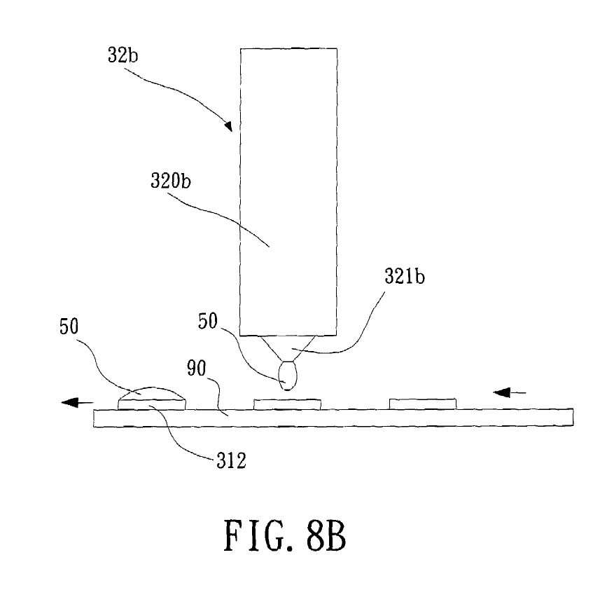

Please refer to FIG. 8A, which is a schematic diagram showing a droplet formation device according to a second embodiment of the invention. As seen in FIG. 8A, the droplet formation device 32a creates droplets by a soaking means, that is, as the carrier 90 is traveling across a container 320a containing a liquid, the pedestals of the carrier 90 is enabled to soak in the liquid and thus droplets can be congregated on each pedestal with respect to the hydrophobic/hydrophilic properties thereof as soon as the carrier exits the container 320a. In addition, the droplet formation device 32 can substantially a nebulizer selected from the group consisting of a piezoelectric nebulizer, a thermal-bubble type nebulizer and an ultrasonic nebulizer. Please refer to FIG. 8B, is a schematic diagram showing a droplet formation device according to a third embodiment of the invention. In FIG. 8B, the droplet formation device 32b creates droplets 50 by a dripping means, which is substantially a liquid-containing container 320 having a dripping hole 321b arranged at a bottom thereof. By controlling the dripping of the dripping hole 321b, droplets can be generated and placed on the pedestals corresponding thereto.

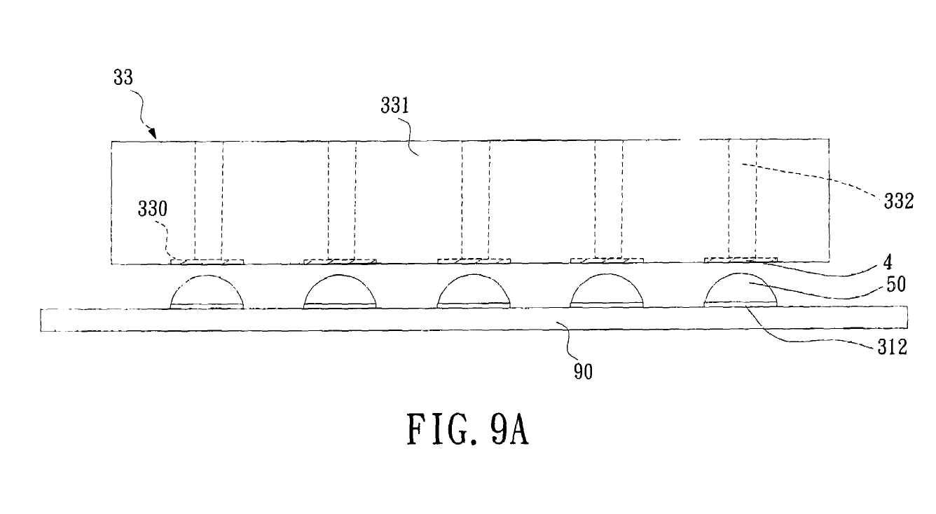

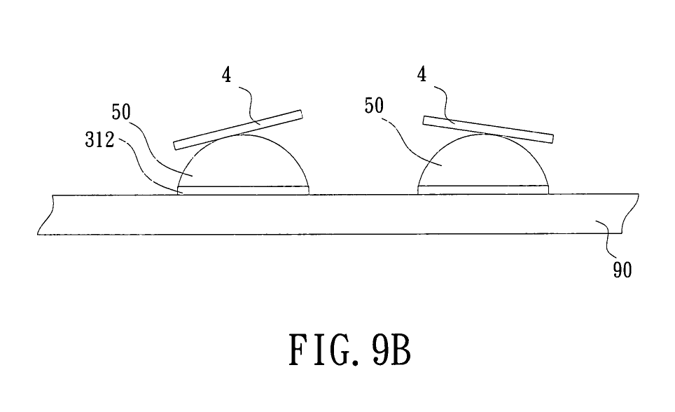

Please refer to FIG. 9A, which is a schematic diagram showing a chip placing device of the invention. The chip placing device 33 is used for providing a plurality of microstructures 4 while placing each microstructure 4 on a droplet 50 corresponding thereto. In the embodiment shown in FIG. 9A, the chip placing device 33 is substantially a supporting board 331 having a plurality of holes 330 formed therein, whereas each hole 330 is capable of receiving a microstructure 4 while the microstructure 4 hold securely by the negative pressure exerted thereon by a corresponding vacuum channel 332. Please refer to FIG. 9B, which is a schematic diagram showing the placing of microstructures on droplets. By the use of the aforesaid chip placing device 33, each microstructure 4 can be placed on its corresponding droplet 50.

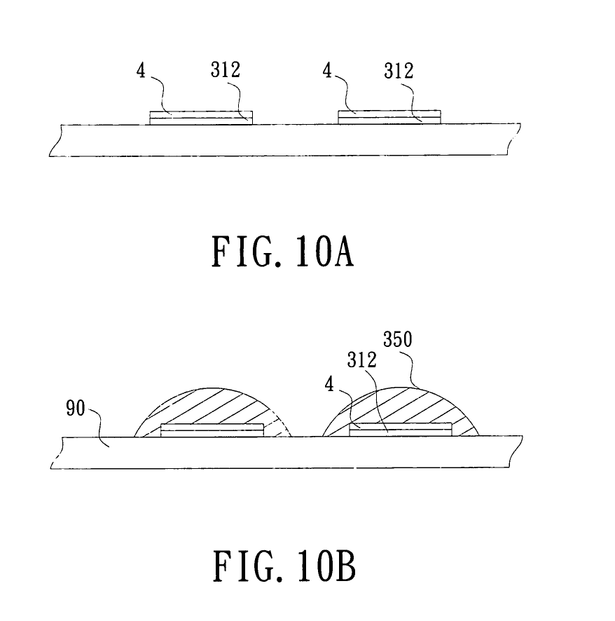

Moreover, in FIG. 4, the droplet removal device 34 is capable of receiving the carrier 90 carrying the plural microstructures 4 while removing each droplet 50 for jointing each microstructure 4 with its corresponding joint 901. In a preferred aspect, the droplet removal device 34 can remove the droplets by allowing to dry naturally, or drying by heating. After the droplets 50 are removed, as seen in FIG. 5B and FIG. 10A, each microstructure 4 is stacking directly on its corresponding pedestal 312 while each is in contact with a joint corresponding thereto. Therefore, as seen in FIG. 4 and FIG. 10B, a pasting device 35 is adopted for receiving the carrier 90 exiting from the droplet removal device 34 while proving a paste 350 to the carrier 90 for securing each microstructure 4 on the carrier 90. In a preferred aspect, the pasting device 35 further comprises: a pasting unit, for providing the paste 350 to be coated on each microstructure 4; a baking unit, for curing the paste 350; and a cooling unit, for cooling the paste 350. It is preferred to use a testing device to examine the electrical properties of the integrate device of the joint and the microstructure 4, after the paste is cured.

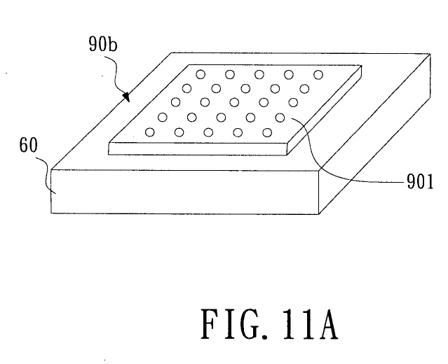

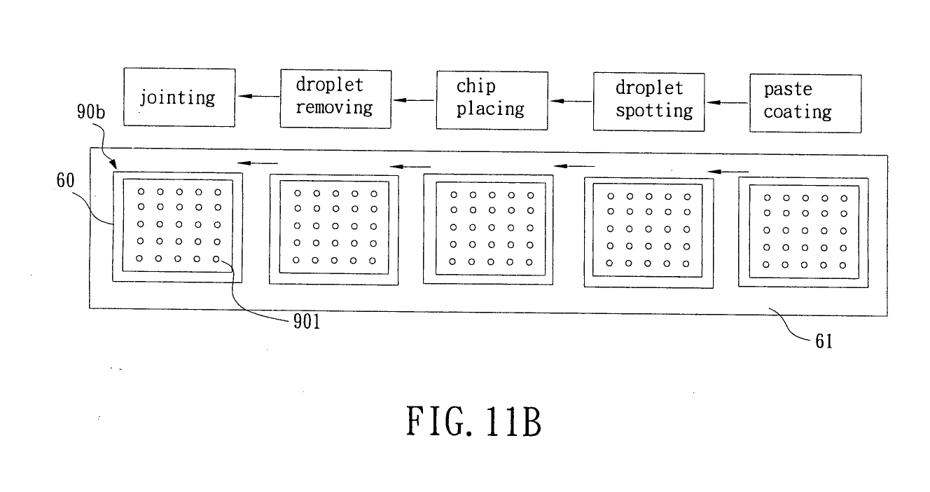

Please refer to FIG. 11A, which is a schematic view of a carrier according to another preferred embodiment of the invention. Except for the abovementioned roll-to-roll carrier, the carrier 90b can be a flexible substrate or printed circuit board, previously cut into a specific size, lo whereas the previous-cut substrate is placed on a platform 60. Moreover, the platform 60 carrying the substrate 90b is being transported by a platform transportation device 61, such as a conveyer belt or a device capable of moving the platform in a step-by-step manner.

As seen in. FIG. 9B, a surface tension of the droplet 50 will force the microstructure 4 float on top of the pedestal 312 as soon as the microstructure 4 comes into contact with the droplet 50, and then, by the operation of minimal surface free energy, the microstructure 4 is self-aligned to the pedestal 312. That is, by the edge effect caused from the affecting of the edge of the pedestal 312 upon the droplet 50, there can be only a position corresponding to the minimal surface free energy, and thus the microstructure 4, affected by the minimal surface free energy, will approach that position such that it is aligned. It is noted that the aforesaid method can be applied in an array-type apparatus for rapidly packaging massive small chips, as seen in FIG. 11B.

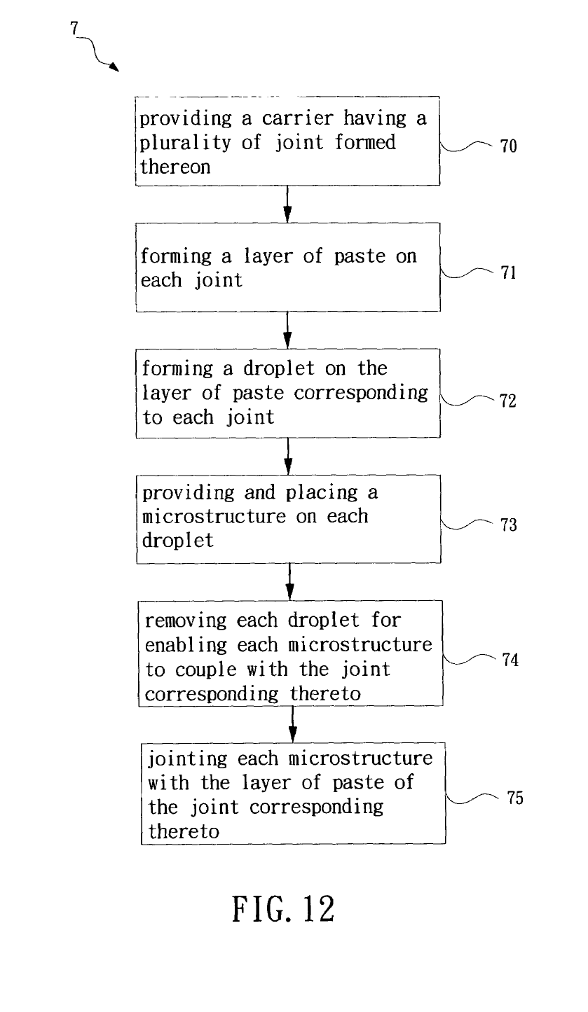

Please refer to FIG. 12, which is a flow chart depicting 7 a method for microstructure assembly according to a second preferred embodiment of the invention. The flow starts at step 70. At step 70, a carrier 40 is provided, which has a plurality of joint formed thereon to be used for forming electrical connections with microstructures, and then the flow proceeds to step 71. In a preferred aspect, the carrier 40 can be a roll-to-roll carrier, or a flexible substrate or printed circuit board, previously cut into a specific size, and each microstructure can be a RFID chip, a LED chip or other passive components. At step 71, a layer of paste is formed on each joint, and then the flow proceeds to step 72. At step 72, a droplet is formed on the layer of paste corresponding to each joint, whereas the droplet can be made of a material selected from the group consisting of water, oil, alcohol, liquid-state paste, and liquid-state metal, and then the flow proceeds to step 73. At step 43, a microstructure is provided and placed on each droplet, and then the flow proceeds to step 74. At step 74, each droplet is removed for enabling each microstructure to couple with the joint corresponding thereto, and then the flow proceeds to step 75. At step 75, each microstructure is jointed with the layer of paste of the joint corresponding thereto; whereas the jointing of each microstructure with the layer of paste of the joint corresponding thereto can be performed by a means selected from the group consisting of a heating means, and an ultrasonic means.

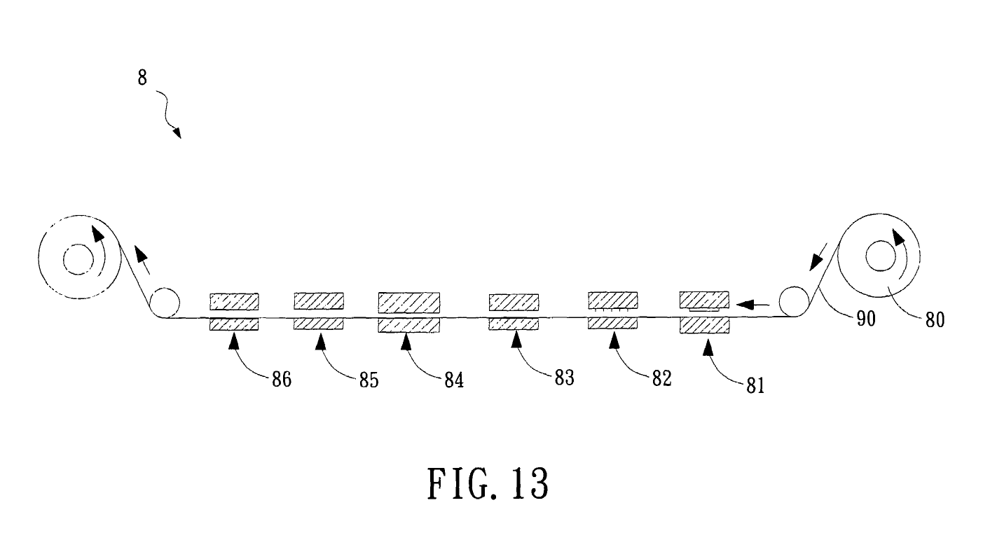

Please refer to FIG. 13, which is a schematic diagram showing yet another assembly apparatus according to a third preferred embodiment of the invention. In this embodiment, the assembly apparatus 8 is a roll-to-roll apparatus. The assembly apparatus 8 of FIG. 4 is provided for enabling the aforesaid method for microstructure assembly, which comprises: a transportation device, a transfer imprinting device, a droplet formation device, a chip placing device, a droplet removal device, and a jointing device. The transportation device 30 is used for transporting a carrier 90 having a plurality of joints formed thereon. It is noted that the transportation device illustrated in this first embodiment is a roll-to-roll device. In addition, the transportation device, the transfer imprinting device, the droplet formation device, the chip placing device, and the droplet removal device are all similar to those of FIG. 4, and thus are not described further herein.

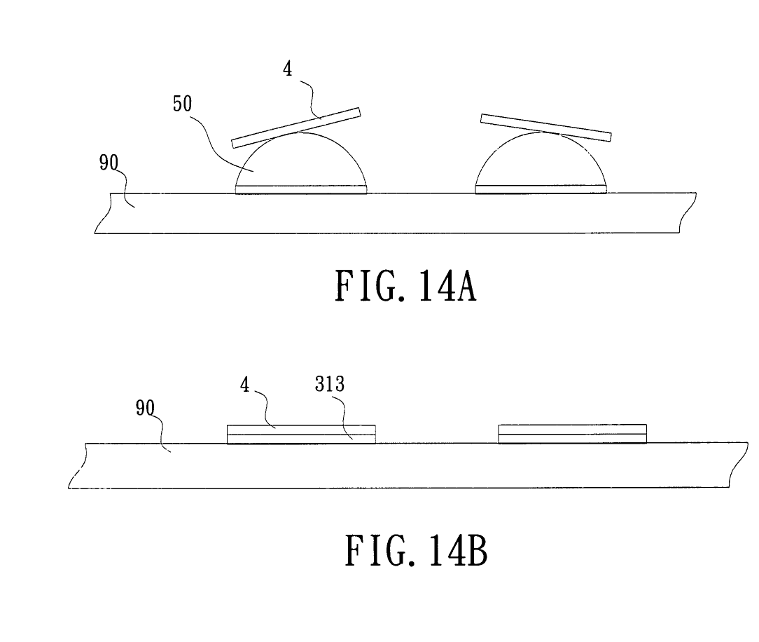

The jointing device of FIG. 13 is substantially paste transfer imprinter, which is capable of transferring and forming a layer of paste by imprinting roller or screen printing, as those shown in FIG. 6A and FIG. 6B. After a paste layer is formed, the droplet formation device is enabled to form droplets on the layer of paste corresponding thereto. Thereafter, the chip placing device is enabled to place microstructures on the droplets corresponding thereto, and then the droplets are removed by the droplet removal device enabling each microstructure to couple with the joint corresponding thereto, as seen in FIG. 14B. Finally, the jointing device is used for securing each microstructure on the carrier. In a preferred aspect, the joint device is a device selected from the group consisting of an ultrasonic bonding device and a heating device.

It is noted that the microstructures referred in the present invention is not limited to be electronic components, such as the aforesaid RFID chips, LED chips or other passive electronic components, which are only referred as an illustration of the invention, and thus is not limited thereby. To sum up, the method and apparatus for microstructure assembly is capable massively and rapidly packaging microstructures in great alignment precision, that is an improvement over the prior art.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A method for microstructure assembly, comprising steps of:
providing a carrier having a plurality of joint formed thereon;
forming a pedestal on each joint;
forming a droplet on each pedestal;
placing a microstructure on each droplet;
removing each droplet for enabling the corresponding microstructure to couple with the joint corresponding thereto; and
using a holding means for securing each microstructure upon the carrier.

2. The method of claim 1, wherein the droplet is formed by a means selected from the group consisting of a nebulization means, a soaking means, a dripping means and a means of arranging a liquid in a container with a plurality of orifices while using the plural orifices for forming droplets. In a preferred aspect, a pressure can be exerted upon the solution in the container.

3. The method of claim 2, further comprising a step of:
exerting a pressure upon the liquid of the container.

4. The method of claim 1, wherein the securing of each microstructure upon the carrier further comprises steps of:
dispensing a paste on each microstructure; and
curing the paste.

5. A method for microstructure assembly, comprising steps of:
providing a carrier having a plurality of joint formed thereon;
forming a layer of paste on each joint;
forming a droplet on the layer of paste corresponding to each joint;
providing and placing a microstructure on each droplet;
removing each droplet for enabling each microstructure to couple with the joint corresponding thereto; and
jointing each microstructure with the layer of paste of the joint corresponding thereto.

6. The method of claim 5, wherein the droplet is formed by a means selected from the group consisting of a nebulization means, a soaking means, a dripping means and a means of arranging a liquid in a container with a plurality of orifices while using the plural orifices for forming droplets. In a preferred aspect, a pressure can be exerted upon the solution in the container.

7. The method of claim 6, further comprising a step of:
exerting a pressure upon the liquid of the container.

8. The method of claim 5, wherein the jointing of each microstructure with the layer of paste of the joint corresponding thereto can be performed by a means selected from the group consisting of a heating means, and an ultrasonic means.

9. An apparatus for microstructure assembly, comprising:
a transportation device, for transporting a carrier having a plurality of joints formed thereon;
a transfer imprinting device, for receiving the carrier while forming a pedestal on each joint;
a droplet formation device, for receiving the carrier with pedestals formed thereon while forming a droplet on each pedestal;
a chip placing device, for providing a plurality of microstructures while placing each microstructure on a droplet corresponding thereto;
a droplet removal device, for receiving the carrier carrying the plural microstructures while removing each droplet for jointing each microstructure with its corresponding joint; and
a pasting device, for receiving the carrier exiting from the droplet removal device while proving a paste to the carrier for securing each microstructure on the carrier.

10. The apparatus of claim 9, wherein the droplet formation device further comprises:
a container, having an accommodating space for receiving a liquid, and a plurality of orifices formed on a side thereof while each being channeling to the accommodating space.

11. The apparatus of claim 10, further comprising:
a pressure unit, for providing a pressure to be exerted on the liquid.

12. The apparatus of claim 9, wherein the droplet formation device is substantially a nebulization device.

13. The apparatus of claim 12, wherein the nebulization device is a device selected from the group consisting of a piezoelectric nebulizer, a thermal-bubble type nebulizer and an ultrasonic nebulizer.

14. The apparatus of claim 9, wherein the pasting device further comprising:
a pasting unit, for providing a paste to be dispensed on each microstructure;
a baking unit, for curing the paste; and
a cooling unit, for cooling the paste.

15. An apparatus for microstructure assembly, comprising:
a transportation device, for transporting a carrier having a plurality of joints formed thereon;
a transfer imprinting device, for receiving the carrier while forming a layer of a paste on each joint,
a droplet formation device, for receiving the carrier coated with the paste while forming a droplet on the layer of paste corresponding to each joint;
a chip placing device, for providing a plurality of microstructures while placing each microstructure on a droplet corresponding thereto;
a droplet removal device, for receiving the carrier carrying the plural microstructures while removing each droplet for jointing each microstructure with its corresponding joint; and
a jointing device, capable of providing energy for jointing each microstructure with its corresponding layer of paste.

16. The apparatus of claim 15, wherein the droplet formation device further comprises:
a container, having an accommodating space for receiving a liquid, and a plurality of orifices formed on a side thereof while each being channeling to the accommodating space

17. The apparatus of claim 16, further comprising:
a pressure unit, for providing a pressure to be exerted on the liquid.

18. The apparatus of claim 15, wherein the droplet formation device is substantially a nebulization device.

19. The apparatus of claim 18, wherein the nebulization device is a device selected from the group consisting of a piezoelectric nebulizer, a thermal-bubble type nebulizer and an ultrasonic nebulizer.

20. The apparatus of claim 15, wherein the joint device is a device selected from the group consisting of an ultrasonic bonding device and a heating device.
